(19) United States
(12) Patent Application Publication
(10) Pub. No.: US 2014/0352889 A1
(43) Pub. Date: Dec. 4, 2014

(54) APPARATUS FOR PROCESSING A SEMICONDUCTOR WORKPIECE

(71) Applicant: SPTS TECHNOLOGIES LIMITED, Newport (GB)

(72) Inventors: OLIVER ANSELL, BRISTOL (GB); BRIAN KIERNAN, CARDIFF (GB); TOBY JEFFERY, CAERPHILLY (GB); MAXIME VARVARA, COPPONEX (FR)

(73) Assignee: SPTS TECHNOLOGIES LIMITED, Newport (GB)

(21) Appl. No.: 14/285,730

(22) Filed: May 23, 2014

(30) Foreign Application Priority Data
May 29, 2013 (GB) 1309583.1

(51) Int. Cl. H01L 21/02

(52) U.S. Cl. CPC H01L 21/02019
USPC 156/345.35; 156/345.1

(57) ABSTRACT

An apparatus for processing a semiconductor workpiece includes a first chamber having a first plasma production source and a first gas supply for introducing a supply of gas into the first chamber, a second chamber having a second plasma production source and a second gas supply for introducing a supply of gas into the second chamber, a workpiece support positioned in the second chamber, and a plurality of gas flow pathway defining elements for defining a gas flow pathway in the vicinity of the workpiece when positioned on the workpiece support. The gas flow path defining elements include at least one wafer edge region protection element for protecting the edge of the wafer and/or a region outwardly circumjacent to the edge of the wafer, and at least one auxiliary element spaced apart from the wafer edge region protection element to define the gas flow pathway.

### CROSS-REFERENCE TO RELATED APPLICATIONS

A claim of priority is made to UK Patent Application 1309583.1, filed May 29, 2013, the disclosure of which is incorporated herein in its entirety.

### BACKGROUND

This invention relates to apparatus for processing a semiconductor workpiece.

Plasma etching is extensively used in the fabrication of semiconductor devices. Cost effective manufacturing of devices requires plasma etch systems to remove the required layers quickly while maintaining the customer specified uniformities (such as etch rate, and selectivity) within and between processed wafers. Frequently there is a compromise to be made between average etch rate and uniformity as in many cases uniformities in the process performance degrade as etch rate is increased.

High rate anisotropic plasma etching of features in silicon wafers is typically achieved by the “Bosch process” [U.S. Pat. No. 5,501,893] or cyclic deposition/etch processes [U.S. Pat. No. 8,133,349]. Deposition and etch steps are cyclically carried out in a plasma etch tool to enable a relatively high removal rate of the silicon which is not protected by the mask. This type of process has widespread commercial application and is used to fabricate MEMS (micro electro mechanical systems), gyroscopes, accelerometers, sensors, through silicon vias (TSVs) and even wafer scribing or thinning. In all cases for cost reasons it is desirable to fabricate the part as rapidly as possible and as a consequence a great deal of effort has been applied to developing hardware and processes that enable the high etch rate of silicon.

It should however be understood that process uniformity is also a very important consideration. In most applications a number of parts (die) are patterned over a wafer and amount of material being removed from all parts should be similar. Ideally they should be the same but in practice achieving identical conditions can be very difficult to achieve. Parts at the centre and the edge of the wafer should be processed in a similar fashion if the maximum yield is to be maintained. It is also desirable that etch rate is the same or similar across the whole wafer. If this is not the case some parts will be completed prior to others and in some cases this may prove to be detrimental to the parts that experience over etching. To complicate matters further plasma uniformity may also influence angle of a feature being etched into the masked silicon wafer. Frequently at the edge of the wafer some of the ions hit the wafer surface at less than normal incidence. This results in a slight “tilt” in the anisotropic feature being etched. U.S. Pat. No. 5,683,548 describes an ICP reactor where independent control of gas and RF can be applied to a series of concentric channels. By using concentric channels—generally in the same plane—some degree of radial plasma non-uniformity can be reduced near the channels. However, non-uniformities can still exist close to the wafer surface.

### SUMMARY

The present invention, in at least some of its embodiments, addresses the abovementioned problems.

According to a first aspect of the invention there is provided an apparatus for processing a semiconductor workpiece including:

a first chamber having a first plasma production source and a first gas supply for introducing a supply of gas into the first chamber;

a second chamber having a second plasma production source and a second gas supply for introducing a supply of gas into the second chamber, the second gas supply being independently controllable of the first gas supply;

a workpiece support positioned in the second chamber; and

a plurality of gas flow pathway defining elements for defining a gas flow pathway in the vicinity of the workpiece when positioned on the workpiece support, wherein the gas flow path defining elements include at least one wafer edge region protection element for protecting the edge of the wafer and/or a region outwardly circumjacent to the edge of the wafer, and at least one auxiliary element spaced apart from the wafer edge region protection element to define the gas flow pathway.

The wafer edge region protection device element may be an annular wafer edge protection device.

The auxiliary element may include one or more baffles. At least one auxiliary element may be an annular baffle.

The auxiliary element may be positioned over an inner portion of the wafer edge region protection element.

The auxiliary element may be positioned over an outer part of the wafer edge region protection element.

The auxiliary element may extend radially inward of the wall of the second chamber.

The auxiliary element may extend downwardly from the wall of the second chamber.

The auxiliary element may be spaced apart from the wafer edge region protection element to define a gap of between 2 and 80 mm, preferably between 5 and 50 mm, most preferably between 15 and 25 mm.

The gas flow pathway may extend radially outwards from the workpiece when positioned on the workpiece support.

The workpiece, when positioned on the workpiece support, may be supported by a carrier, and the wafer edge region protection element protects the carrier. The carrier may be of the tape and frame kind. The wafer edge protection element may protect the tape and/or the frame.

The first plasma production source may include an element for coupling energy into the first chamber to maintain a plasma induced in the first chamber, and the second plasma production source may include an element for coupling energy into the second chamber to maintain a plasma induced in the second chamber, wherein the element of the first plasma production source is spaced apart from the element of the second plasma production source so as to decouple the plasma induced in the first chamber from the plasma induced in the second chamber. The apparatus may be configured so that no energy or only insignificant amounts of energy from the element for coupling energy into the first chamber is coupled into the second plasma. Alternatively, or additionally, the apparatus may be configured so that no energy or only insignificant amounts of energy from the element for coupling energy into the second chamber is coupled into the first plasma. In this way, the plasmas may be decoupled. The elements for coupling energy into the first and second chambers may be RF coils. The first chamber may meet the second chamber at an interface having an associated level, and at least one of the elements of the first plasma production source and the elements of the second plasma production source may be spaced apart from said level.

The skilled reader will appreciate that the auxiliary element is an element which is additional to the wall of the second chamber, although it may project from said wall.

According to a second aspect of the invention there is provided an apparatus for processing a semiconductor workpiece including;

a first chamber having a first plasma production source including an element for coupling energy into the first chamber to maintain a plasma induced in the first chamber, and a first gas supply for introducing a supply of gas into the first chamber;

a second chamber having a second plasma production source including an element for coupling energy into the first chamber to maintain a plasma induced in the second chamber and a second gas supply for introducing a supply of gas into the second chamber, the second gas supply being independently controllable of the first gas supply; and

a workpiece support positioned in the second chamber;

wherein the element of the first plasma production source is spaced apart from the element of the second plasma production source so as to decouple the plasma induced in the first chamber from the plasma induced in the second chamber.

According to a third aspect of the invention there is provided an apparatus for processing a semiconductor workpiece including:

a chamber having a wall;

a workpiece support positioned in the chamber;

at least one plasma production source; and

a plurality of gas flow pathway defining elements for defining a gas flow pathway in the vicinity of the workpiece when positioned on the workpiece support, wherein the gas flow pathway defining elements include at least one wafer edge region protection element for protecting the edge of the wafer and/or a region outwardly circumjacent to the edge of the wafer, and at least one auxiliary element spaced apart from the wafer edge region protection element to define the gas flow pathway.

According to a fourth aspect of the invention there is provided a method of cleaning a chamber of an apparatus including the steps of:

providing an apparatus for processing a semiconductor workpiece according to the first or second aspects of the invention;

generating a cleaning plasma in the first and/or the second chambers; and

using the plasma to selectively clean a specific area of the apparatus.

Whilst the invention has been described above, it extends to any inventive combination of the features set out above, or in the following description, drawings or claims.

### BRIEF DESCRIPTION OF THE DRAWINGS

Embodiments of apparatus in accordance with the invention will now be described with reference to the accompanying drawings, in which:

FIG. 1 shows a first embodiment of an apparatus of the invention;

FIG. 2 shows a second embodiment of an apparatus of the invention;

FIGS. 3A and 3B show plasma cleaning of (a) the second chamber and (b) the first chamber of the apparatus of FIG. 1;

FIG. 4 shows normalised etch rate as a function of radial wafer position for a single RF source configuration and a dual RF source configuration;

FIG. 5 shows normalised etch rate as a function of radial wafer position for a single RF source configuration with gas feed and a dual RF source configuration with separate gas feeds; and

FIG. 6 shows etch rate uniformity with and without a gas conductance limiting pathway at the edge of a 200 mm blank silicon wafer.

### DETAILED DESCRIPTION OF EMBODIMENTS

Inductively coupled plasma (ICP) Plasma etch tools frequently use an RF antenna placed around a ceramic bell jar to produce a dense plasma. A central gas feed provides the gas to be disassociated in the bell jar and plasma non-uniformities are reduced through the use of a “diffusion chamber” a large diameter chamber which is placed between the plasma source and the wafer platen assembly. The diffusion chamber allows the plasma to expand to beyond the edge of the wafer. Gas is pumped from the chamber through a gate valve to the bottom of the system. The platen assembly will normally have an electrostatic chuck to aid heat removal from the wafer and an RF bias to aid the etch/deposition process. Although the invention is not limited to ICP plasma etch tools, for the purposes of illustration the invention will now be described in relation to etch tools of this type.

In the context of RF based, ICP plasma etch tools described in the accompanying drawings, features of the invention are as follows: a) two concentric RF sources, the primary source being located in the upper bell jar and the diameter of this jar being lower than that of the main chamber; b) two gas feeds, one to the primary source and the other being an annular arrangement to the upper part of the main chamber; and c) a conductance limiting path at the edge of the wafer to reduce the flow of gas at the wafer edge.

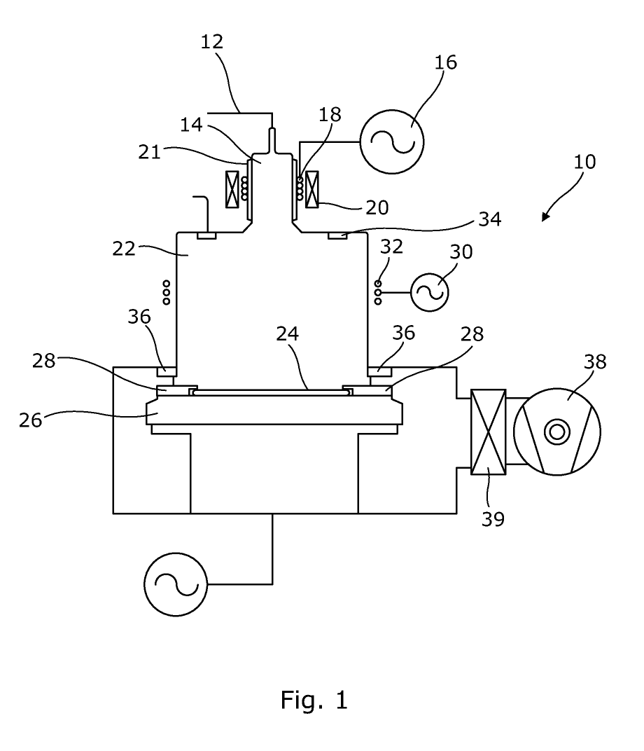

By judicious control of one or more of these factors, etch rate can be enhanced while uniformity can be maintained at acceptable levels. These features can be seen diagrammatically in FIG. 1.

A secondary benefit of the invention is an improved plasma clean process capability. Plasma clean processes can be used to remove deposited material from the chamber walls. This is a very important factor which must be controlled to maintain wafer-wafer uniformity over time. An advantage of the present invention is that because the two plasma sources can be operated independently the operator can run clean regimes targeting specific areas of the chamber, (ICP only for main reaction chamber/high density plasma only for bell jar). The invention also makes it possible to shift the plasma around by using combination of the sources. More efficient cleaning will yield productivity benefits.

FIG. 1 depicts a first configuration of apparatus of the invention, shown generally at 10. The primary gas feed 12 enters the primary chamber 14 (˜7-12 cm diameter dielectric cylinder) which has an associated primary ionization source 16. An RF antenna 18 nominally 13.56 MHz acts as the ICP source. This can be assisted by a DC 20 coil to modify the confinement of the plasma. A Faraday shield 21 can be provided between the DC coil 20 and the wall of the primary chamber 14 to reduce capacitive coupling. The plasma from the primary source enters the main chamber 22 where the wafer 24 is placed on the wafer support 26, which may be an electrostatic chuck. The wafer size could be up to 300 mm in standard production applications, although processing of still larger wafers is within the scope of the invention. The edge of the wafer 24 is protected by a wafer edge protection (WEP) device 28 to avoid excessive loss of silicon at the wafer edge where the resist edge bead has been removed. The main (secondary) chamber 22 has a secondary ionization source 30 having a secondary RF coil 32 placed around the main chamber 22 to provide a secondary plasma close to the chamber wall 22a. The RF coil 32 could also operate at 13.56 MHz or a lower frequency such as 1-2 MHz. It is possible to include a Faraday shield between the secondary RF coil 32 and the wall of the main chamber 22. This can be additional to the Faraday shield 21 positioned adjacent to primary chamber 14. Alternatively, the Faraday shield positioned adjacent the main chamber 22 can be instead of the Faraday shield 21, or no Faraday shield may be present. An annular gas distribution system 34 is incorporated into the main chamber 22 to provide an independent gas source for the secondary plasma. A conductance limiting pathway is introduced at the wafer edge. Gas flows above the WEP 28 and below an annular baffle 36 in a radial fashion to the pump 38 through a gate valve 39. The typical but non-limiting height of this gap is 5-50 mm. The conductance limiting path can increase the residence time of active gas species at the wafer edge and hence improve process uniformity.

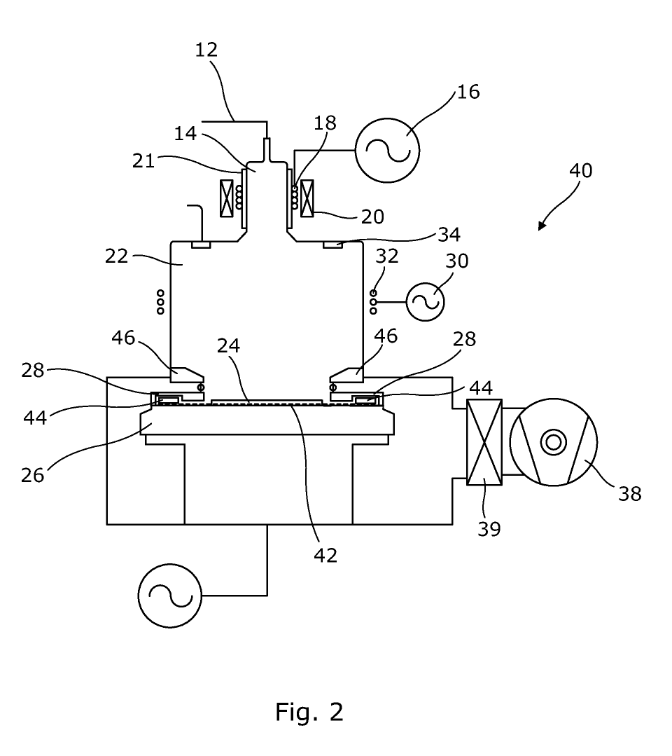

It is desirable that the WEP is maintained at an elevated temperature to reduce the deposition build up due to successive deposition cycles. This heating is preferably achieved by creating a plasma in the chamber 22 to heat all the interior before the wafer of interest is loaded. The plasma during the main process will ensure that the protection system continues to stay at a temperature of 85° C. to 150° C. This WEP system can have an internal diameter greater than the wafer diameter to ensure that the whole wafer is exposed to the plasma, but material is protected outside the wafer diameter. This material could include the tape and/or frame of a wafer supported by tape or an alternative carrier. Such a configuration is shown in FIG. 2. FIG. 2 depicts a second configuration of apparatus of the invention, shown generally at 40. Many of the elements shown in FIG. 2 are identical to elements shown in FIG. 1, and identical reference numerals are used to denote such common elements.

In FIG. 2 the wafer 24 is carried on a tape 42 and frame 44 arrangement. A wafer edge conductance limiting baffle 46 is attached above the wafer position, with an inner diameter close to the diameter of the wafer 24. The gap between the wafer 24 (or parts sitting on the wafer support 26 around the wafer 24) should be small enough to cause the etchant gas to mainly interact with the wafer 24 before being pumped around the side of the wafer support 26. In FIG. 2 the gap between the WEP 28 which protects the tape 42 and frame 44 and the baffle 46 is identified by the arrow. A balance must be found between this mixing and the reduced conductance that this causes for pumping the etch products away from the wafer. As a guideline, the optimum gap size is often between 15 and 25 mm, although other constraints may cause the gap to be 5 to 50 mm. The baffle is applicable to many etch materials and process gases where a remote plasma source is used, including, but not limited to, Si, GaAs, polymer, Al, and fluorine, chlorine and oxygen based chemistries.

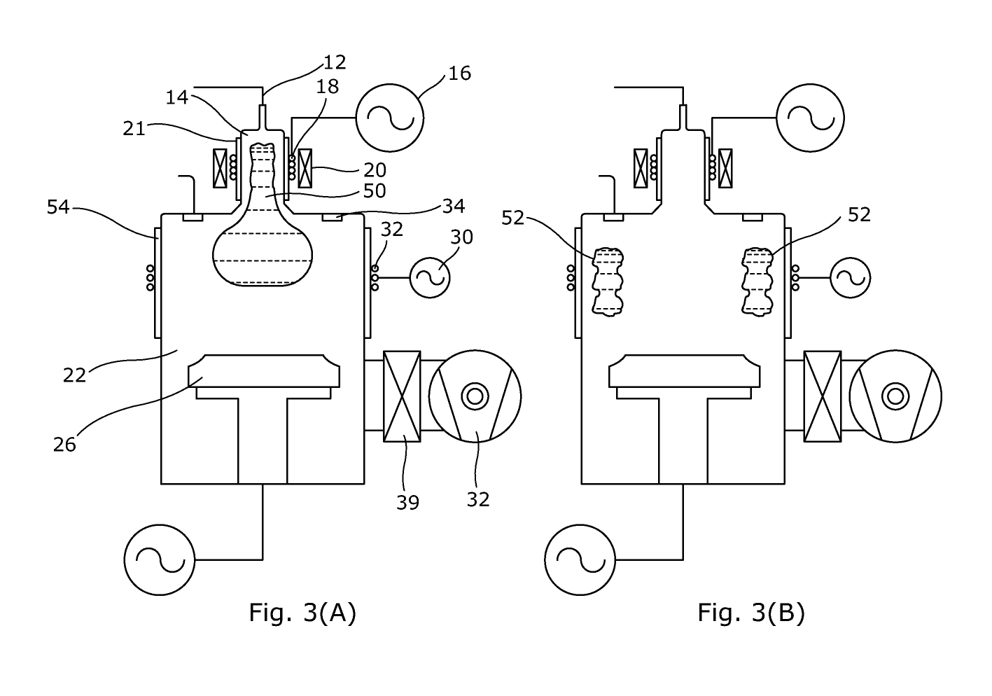

Cleaning the process chamber following an etch cycle or number of wafers is essential if process reproducibility is to be maintained over time. Plasma clean processes can be used to remove deposited material from the chamber walls and in turn increase the time between venting the chamber for a maintenance clean. The present invention provides apparatus having two plasma sources which can be operated independently, enabling specific clean regimes to be implemented which target specific areas of the chambers (ICP only for main chamber/high density plasma only for bell jar (primary chamber)). FIG. 3 shows a) plasma cleaning of the primary chamber 14 and b) plasma cleaning of the primary chamber 22 using apparatus of the invention. The apparatus shown in FIG. 3 is essentially identical to the apparatus 10 shown in FIG. 1, and identical reference numerals are used to denote common elements. The apparatus shown in FIG. 3 further comprises a second Faraday shield 54 provided between the secondary RF coil 32 and the wall of the main chamber 22. In FIG. 3 a) a plasma 50 is produced in the primary chamber 14, and in FIG. 3b) a plasma 52 is produced in the main chamber 22. This approach also makes it possible to shift the plasma around by using combination of the sources. More efficient cleaning will yield productivity benefits.

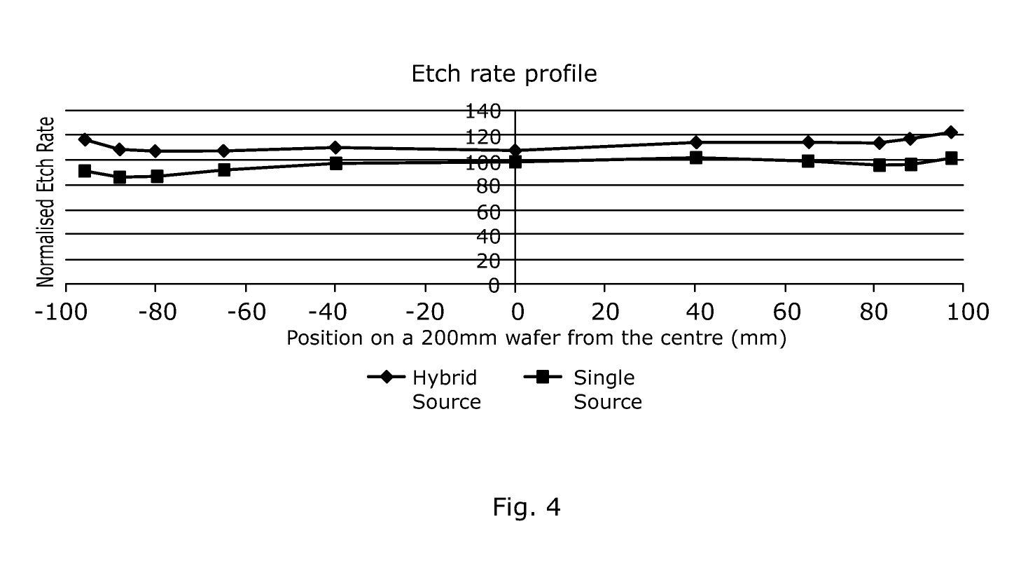

By using two independent sources—one primary source at the top of the chamber in a small ceramic/insulating container where the principal dissociation of the reactive gases will take place—and secondary auxiliary source between the primary source and the wafer—ideally close to the wafer—radial non-uniformities close to the wafer edge can be compensated by the auxiliary source. When using a single source the plasma density at the centre of the process chamber tends to be higher than at the edge. This is particularly pronounced using a small diameter tube as the first chamber. As the RF power applied to the antenna is increased, the non-uniformity can be increased. In FIG. 4 we can see not only improved uniformity for 200 mm wafers but also higher normalised etch rate due to the use of the secondary RF source. The RF power for the primary source was maintained a 3 kW for both sets of data but 1.5 kW power was used in the secondary source for the “hybrid source” measurements. Gas was only supplied to the primary source.

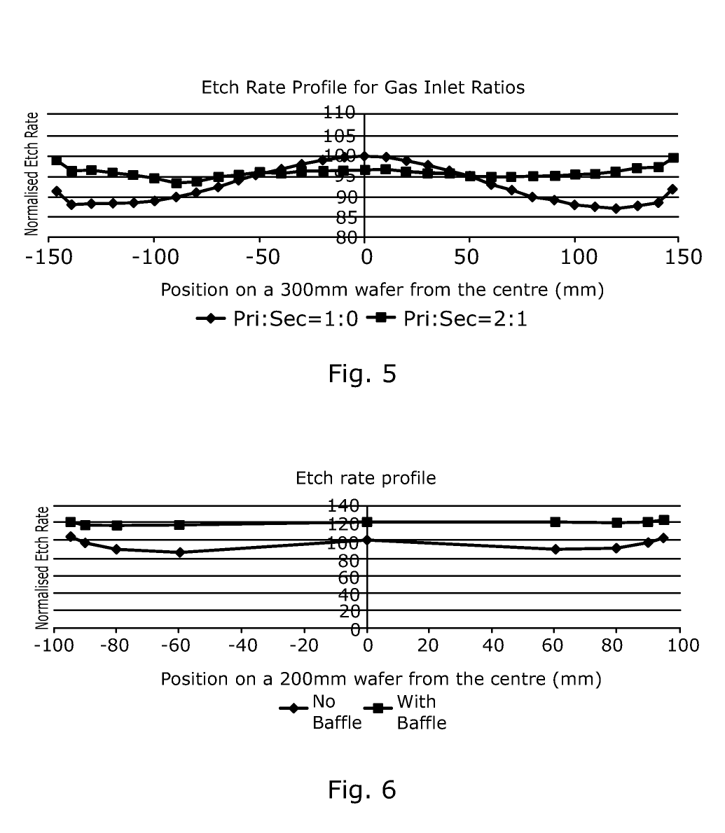

The benefit of having an independent annular gas supply to the secondary RF source can be seen in FIG. 5. Here the normalized etch rate for a 300 mm wafer can be seen gas flow solely to the primary source and when gas is supplied with a ratio of 2:1 between the primary and secondary sources. Increasing the gas low to the annular gas supply to the main chamber improves the uniformity of the plasma and in turn improves etch uniformity.

In FIG. 6 we can see the benefit of utilizing a conductance limiting path (baffle/WEP channel) at the edge of the wafer. Uniformity can be improved by reducing the depletion of reactive species at the wafer periphery and reducing the number of ions. This improves the uniformity across the wafer and therefore also allows a higher etch rate for a given uniformity by adjusting other process parameters which would normally worsen the uniformity.

The invention could be applied to semiconductor wafers, wafers on carriers or wafer in frames. The principal adjustment is the positioning of the WEP and the baffle to ensure the conductance limiting path is controlled to improve edge uniformity. In the case of wafers in frames the WEP would cover the frame and much of the exposed tape but not the wafer edge.

Numerous variations to the specific embodiments described above are within the scope of the invention. For example, instead of using Faraday shields, an alternative means may be used to reduce stray electric coupling, such as a segmented coil. Such a coil structure could be mounted inside a chamber, as described in U.S. Pat. No. 6,495,963. Alternative magnetic plasma confinement means may be used in place of DC coils, and in other embodiments no magnetic plasma confinement means are used at all. The frequencies of the RF sources do not have to be the same, and any suitable combination of frequencies might be used. A non-limiting range of possible frequencies is 1-13.56 MHz.

What is claimed is:

1. An apparatus for processing a semiconductor workpiece including:
a first chamber having a first plasma production source and a first gas supply for introducing a supply of gas into the first chamber;
a second chamber having a second plasma production source and a second gas supply for introducing a supply of gas into the second chamber, the second gas supply being independently controllable of the first gas supply;
a workpiece support positioned in the second chamber; and
a plurality of gas flow pathway defining elements for defining a gas flow pathway in the vicinity of the workpiece when positioned on the workpiece support, wherein the gas flow path defining elements include at least one wafer edge region protection element for protecting the edge of the wafer and/or a region outwardly circumjacent to the edge of the wafer, and at least one auxiliary element spaced apart from the wafer edge region protection element to define the gas flow pathway.

2. An apparatus according to claim 1 in which the wafer edge region protection device element is an annular wafer edge protection device.

3. An apparatus according to claim 1 in which the at least one auxiliary element includes one or more baffles.

4. An apparatus according to claim 3 at which the at least one auxiliary element is an annular baffle.

5. An apparatus according to claim 1 in which the auxiliary element is positioned over an inner portion of the wafer edge region protection element.

6. An apparatus according to claim 1 in which the auxiliary element is positioned over an outer part of the wafer edge region protection element.

7. An apparatus according to claim 1 in which the auxiliary element extends radially inward of the wall of the second chamber.

8. An apparatus according to claim 1 in which the auxiliary element extends downwardly from the wall of the second chamber.

9. An apparatus according to claim 1 in which the auxiliary element is spaced apart from the wafer edge region protection element to define a gap of between 2 and 80 mm, preferably between 5 and 50 mm, most preferably between 15 and 25 mm.

10. An apparatus according to claim 1 in which the gas flow pathway extends radially outwards from the workpiece when positioned on the workpiece support.

11. An apparatus according to claim 1 in which the workpiece, when positioned on the workpiece support, is supported by a carrier, and the wafer edge region protection element protects the carrier.

12. An apparatus according to claim 11 in which the carrier is of the tape and frame kind, and the wafer edge protection element protects the tape and/or the frame.

13. An apparatus according to claim 1 in which the first plasma production source includes an element for coupling energy into the first chamber to maintain a plasma induced in the first chamber, and the second plasma production source includes an element for coupling energy into the second chamber to maintain a plasma induced in the second chamber, wherein the element of the first plasma production source is spaced apart from the element of the second plasma production source so as to decouple the plasma induced in the first chamber from the plasma induced in the second chamber.

14. An apparatus according to claim 13 in which the first chamber meets the second chamber at an interface having an associated level, and at least one of the elements of the first plasma production source and the elements of the second plasma production source is spaced apart from said level.

15. An apparatus for processing a semiconductor workpiece including;
a first chamber having a first plasma production source including an element for coupling energy into the first chamber to maintain a plasma induced in the first chamber, and a first gas supply for introducing a supply of gas into the first chamber;
a second chamber having a second plasma production source including an element for coupling energy into the first chamber to maintain a plasma induced in the second chamber and a second gas supply for introducing a supply of gas into the second chamber, the second gas supply being independently controllable of the first gas supply; and
a workpiece support positioned in the second chamber;
wherein the element of the first plasma production source is spaced apart from the element of the second plasma production source so as to decouple the plasma induced in the first chamber from the plasma induced in the second chamber.

16. An apparatus for processing a semiconductor workpiece including:
a chamber having a wall;
a workpiece support positioned in the chamber;
at least one plasma production source; and
a plurality of gas flow pathway defining elements for defining a gas flow pathway in the vicinity of the workpiece when positioned on the workpiece support, wherein the gas flow pathway defining elements include at least one wafer edge region protection element for protecting the edge of the wafer and/or a region outwardly circumjacent to the edge of the wafer, and at least one auxiliary element spaced apart from the wafer edge region protection element to define the gas flow pathway.
